(19) United States
(12) Patent Application Publication
(10) Pub. No.: US 2025/0264551 A1
(43) Pub. Date: Aug. 21, 2025

(54) METHOD FOR MANUFACTURING MAGNETIC SENSOR AND MAGNETIC SENSOR

(71) Applicant: TDK Corporation, Tokyo (JP)

(72) Inventor: Takafumi KOBAYASHI, Tokyo (JP)

(21) Appl. No.: 19/035,415

(22) Filed: Jan. 23, 2025

(30) Foreign Application Priority Data
Feb. 21, 2024 (JP) 2024-024599

(51) Int. Cl. G01R 33/00; G01R 33/09

(52) U.S. Cl. CPC G01R 33/0005; G01R 33/0052; G01R 33/091

(57) ABSTRACT

A magnetic sensor comprises: a first magnetic field sensing element that includes a magnetic field sensing axis parallel to a first direction, two first magnet layers that are arranged in a second direction perpendicular to the first direction, and a first soft magnetic layer that is sandwiched between the two first magnet layers in the second direction; a second magnetic field sensing element that includes a magnetic field sensing axis parallel to the second direction, two second magnet layers that are arranged in the first direction, and a second soft magnetic layer that is sandwiched between the two second magnet layers in the first direction; and a substrate that supports the first and second magnetic field sensing elements. The first and second magnet layers are magnetized by applying an external magnetic field from a direction that is at approximately equal angles to each of the first and second directions.

### FIELD

This application claims the benefit of Japanese Priority Patent Application No. JP 2024-024599 filed on Feb. 21, 2024, the entire contents of which are incorporated herein by reference.

The present invention relates to a method for manufacturing a magnetic sensor and the magnetic sensor.

### BACKGROUND

Magnetic sensors that can detect magnetic fields in a plurality of directions are known. JP 2014-515470 A describes a magnetic sensor in which two types of sensor bridges are supported on a substrate. The two types of sensor bridges detect two orthogonal magnetic field components. A plurality of magnets is mounted on the substrate to apply a bias magnetic field to each of the sensor bridges, and the magnets are magnetized in the same direction. Each sensor bridge is made up of four elements, and the long axes of two elements are perpendicular to the long axes of the other two elements.

### SUMMARY

In the magnetic sensor described in JP 2014-515470 A, a plurality of magnets can be magnetized in a single process. In addition, a bias magnetic field is applied to stabilize the magnetization state of the elements of the magnetic sensor and to improve the linearity and symmetry of the output. Because the bias field is parallel to the long axis of one set of elements but parallel to the short axis of the other set of elements, stabilizing the magnetization state of the other set of elements is difficult. The magnets may be magnetized so that the magnets each have a different magnetization state according to the orientation of the elements.

The present disclosure relates to a method for manufacturing a magnetic sensor. The magnetic sensor comprises: a first magnetic field sensing element that includes a magnetic field sensing axis approximately parallel to a first direction, two first magnet layers that are arranged in a second direction approximately perpendicular to the first direction, and a first soft magnetic layer that is sandwiched between the two first magnet layers in the second direction; a second magnetic field sensing element that includes a magnetic field sensing axis approximately parallel to the second direction, two second magnet layers arranged in the first direction, and a second soft magnetic layer that is sandwiched between the two second magnet layers in the first direction; and a substrate that supports the first magnetic field sensing element and the second magnetic field sensing element. The method for manufacturing the magnetic sensor comprises a step of applying an external magnetic field from a direction at an angle that is approximately equal to each the first direction and the second direction while the two first magnet layers, the two second magnet layers, the first soft magnetic layer, and the second soft magnetic layer are supported on a substrate, thereby magnetizing the two first magnet layers and the two second magnet layers.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a schematic configuration diagram of a magnetic sensor according to a first embodiment of the present disclosure;

FIG. 2 is a plan view of a magnetization free layer and a magnet layer shown in FIG. 1;

FIG. 3 is a conceptual diagram showing a method of magnetizing a magnet layer;

FIG. 4 is a schematic configuration diagram of a magnetic sensor according to a modification of the first embodiment;

FIG. 5 is a conceptual diagram showing a method for magnetizing a magnet layer of a magnetic sensor according to a second embodiment of the present disclosure;

FIG. 6 is a conceptual diagram showing a method for magnetizing a magnet layer of a magnetic sensor according to a third embodiment of the present disclosure;

FIG. 7 is a conceptual diagram showing a method for magnetizing a magnet layer of a magnetic sensor according to a fourth embodiment of the present disclosure;

FIGS. 8A and 8B are conceptual diagrams showing a method for magnetizing a magnet layer of a magnetic sensor according to a fifth embodiment of the present disclosure; and

FIGS. 9A and 9B are conceptual diagrams showing a method for magnetizing a magnet layer of a magnetic sensor according to a sixth embodiment of the present disclosure.

### DETAILED DESCRIPTION

In the following explanation, some example embodiments and modifications of the technology are described in detail with reference to the accompanying drawings. Note that the following description is directed to illustrative examples of the disclosure and is not to be construed as limiting the technology. Factors including, without limitation, numerical values, shapes, materials, components, positions of the components, and the manner in which components are combined with each other are illustrative only and not to be construed as limiting the technology. Further, elements in the following example embodiments that are not recited in a most-generic independent claim of the disclosure are optional and may be provided on an as-needed basis. The drawings are schematic and are not intended to be drawn to scale. Like elements are denoted with the same reference numerals to avoid redundant descriptions.

An object of the present disclosure is to provide a method for manufacturing a magnetic sensor, the method being capable of magnetizing a plurality of magnet layers to different magnetization states in a single process.

Embodiments of a magnetic sensor according to the present disclosure will be described with reference to the drawings. In the following description and drawings, first direction X is approximately parallel to the magnetic sensing direction of first magnetic field sensing element 2A, and second direction Y is approximately parallel to the magnetic sensing direction of second magnetic field sensing element 2B. Third direction Z coincides with the stacking direction of a laminated body, which will be described later. First direction X and second direction Y are parallel to element mounting surface 3A of substrate 3. First direction X, second direction Y, and third direction Z are approximately perpendicular to one another.

### First Embodiment

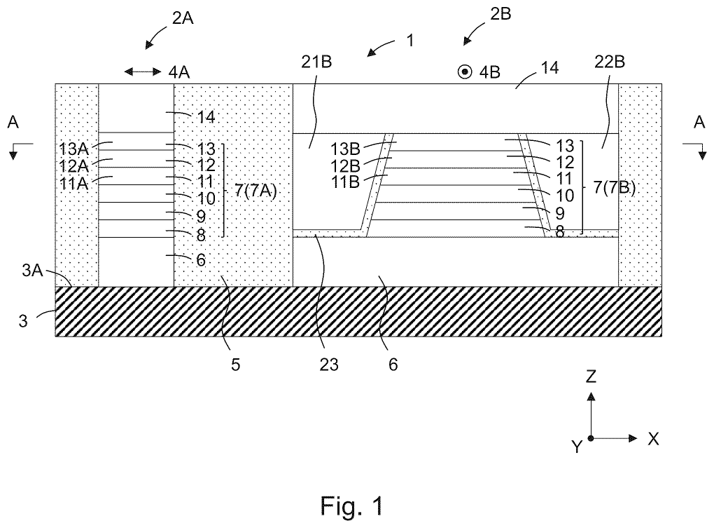

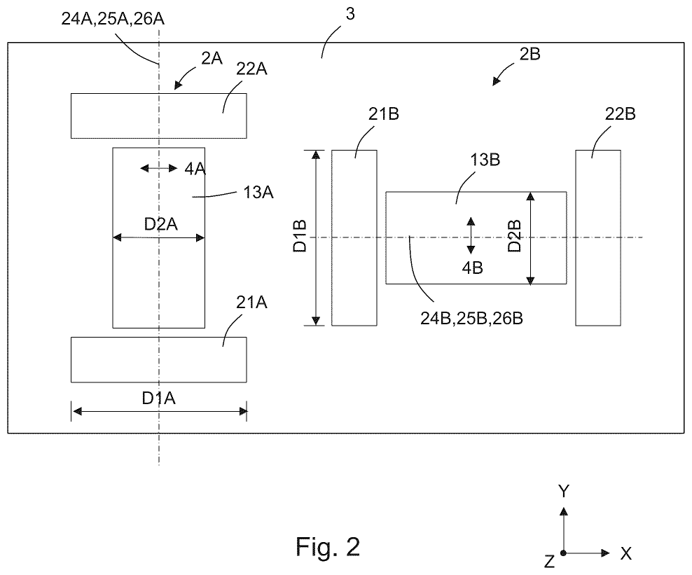

FIG. 1 is a cross-sectional view showing a schematic configuration of magnetic sensor 1 according to the first embodiment, and FIG. 2 is a plan view of a magnetization free layer and magnet layers taken along line AA in FIG. 1. Referring to FIG. 1, magnetic sensor 1 comprises first magnetic field sensing element 2A, second magnetic field sensing element 2B, and substrate 3 that supports first magnetic field sensing element 2A and second magnetic field sensing element 2B. First magnetic field sensing element 2A has magnetic field sensing axis (magnetic field sensing direction) 4A parallel to first direction X, and second magnetic field sensing element 2B has magnetic field sensing axis (magnetic field sensing direction) 4B parallel to second direction Y. First magnetic field sensing element 2A and second magnetic field sensing element 2B have the same configuration, and first (or second) magnetic field sensing element 2A (2B) rotated 90 degrees on the XY plane corresponds to second (or first) magnetic field sensing element 2B (2A). Insulating layer 5 that is made of Al₂O₃ is provided between first magnetic field sensing element 2A and second magnetic field sensing element 2B.

First magnetic field sensing element 2A and second magnetic field sensing element 2B each comprise lower electrode layer 6, laminated body 7, and upper electrode layer 14. Laminated body 7 includes antiferromagnetic layer 8, outer magnetization fixed layer 9, nonmagnetic intermediate layer 10, inner magnetization fixed layer 11, spacer layer 12, and magnetization free layer 13. These layers are stacked in the above order in third direction Z from lower electrode layer 6 to upper electrode layer 14. Inner magnetization fixed layer 11 may be referred to as magnetization fixed layer 11. A sense current flows in laminated body 7 in third direction Z by including lower electrode layer 6 and upper electrode layer 14. In the following explanation, laminated body 7, inner magnetization fixed layer 11, spacer layer 12, and magnetization free layer 13 of first magnetic field sensing element 2A may also be referred to as first laminated body 7A, first magnetization fixed layer 11A, first spacer layer 12A, and first magnetization free layer 13A, respectively. Laminated body 7, inner magnetization fixed layer 11, spacer layer 12 and magnetization free layer 13 of second magnetic field sensing element 2B may also be referred to as second laminated body 7B, second magnetization fixed layer 11B, second spacer layer 12B, and second magnetization free layer 13B, respectively. First magnetization free layer 13A may also be referred to as first soft magnetic layer 13A, and second magnetization free layer 13B may also be referred to as second soft magnetic layer 13B.

Magnetization free layer 13 is a soft magnetic layer in which the magnetization direction is caused to rotate by an external magnetic field, and can be made of, for example, NiFe. Spacer layer 12 is a nonmagnetic layer located between magnetization free layer 13 and magnetization fixed layer 11. Spacer layer 12 may be formed of a nonmagnetic insulator such as Al₂O₃ or MgO, or of a nonmagnetic conductor such as Cu. When spacer layer 12 is a nonmagnetic insulator, first and second magnetic field sensing elements 2A and 2B function as tunneling magnetoresistance (TMR) elements, and when spacer layer 12 is a nonmagnetic conductor, first and second magnetic field sensing elements 2A and 2B function as giant magnetoresistance (GMR) elements. A TMR element has a larger MR change rate than a GMR element, and the output voltage of magnetic sensor 1 can be increased.

Inner magnetization fixed layer 11 is a ferromagnetic layer that is sandwiched between outer magnetization fixed layer 9 and spacer layer 12. Inner magnetization fixed layer 11 is antiferromagnetically coupled to outer magnetization fixed layer 9 via nonmagnetic intermediate layer 10 that is made of, for example, Ru or Rh. Outer magnetization fixed layer 9 is a ferromagnetic layer that is exchange-coupled to antiferromagnetic layer 8. Antiferromagnetic layer 8 can be made of PtMn, IrMn, NiMn, or the like. The magnetization directions of inner magnetization fixed layer 11 and outer magnetization fixed layer 9 are fixed and are antiparallel to each other. The magnetization direction of first magnetization fixed layer 11A is fixed in first direction X, and the magnetization direction of second magnetization fixed layer 11B is fixed in second direction Y. The magnetization direction (first direction X) of first magnetization fixed layer 11A coincides with magnetic field sensing axis 4A of first magnetic field sensing element 2A, and the magnetization direction (second direction Y) of second magnetization fixed layer 11B coincides with magnetic field sensing axis 4B of second magnetic field sensing element 2B.

As shown in FIG. 2, first magnetic field sensing element 2A comprises two first magnet layers 21A and 22A arranged in second direction Y. First magnet layers 21A and 22A sandwich first magnetization free layer 13A in second direction Y. First magnet layers 21A and 22A apply a bias magnetic field in second direction Y to first magnetization free layer 13A. Second magnetic field sensing element 2B has two second magnet layers 21B and 22B arranged in first direction X. Second magnet layers 21B and 22B sandwich second magnetization free layer 13B in first direction X. Second magnet layers 21B and 22B apply a bias magnetic field in first direction X to second magnetization free layer 13B. First magnet layers 21A and 22A and second magnet layers 21B and 22B have the same configuration and shape.

First and second magnet layers 21A, 22A, 21B, and 22B are made of a hard-magnetic material such as CoPt or CoCrPt. As shown in FIG. 1, second magnet layers 21B and 22B are provided over almost the entire area in third direction Z of second laminated body 7B. Second magnet layers 21B and 22B may be provided at least on the sides in first direction X of second magnetization free layer 13B. Although not shown, first magnet layers 21A and 22A are provided over almost the entire area in third direction Z of first laminated body 7A. First magnet layers 21A and 22A need only be provided on at least the sides in second direction Y of first magnetization free layer 13A. Insulating layers 23 made of Al₂O₃ or the like are provided between first magnet layers 21A and 22A and first laminated body 7A and between second magnet layers 21B and 22B and second laminated body 7B. Insulating layer 23 prevents the sense current flowing through laminated body 7 from leaking to magnet layers 21A, 22A, 21B, and 22B, and in particular prevents a short circuit between magnetization free layer 13 and magnetization fixed layer 11. Insulating layer 23 is omitted in FIG. 2.

As shown in FIG. 2, first magnetization free layer 13A is formed longer in second direction Y and narrower in first direction X. Therefore, the magnetization direction of first magnetization free layer 13A is easily oriented to second direction Y by the shape anisotropy effect. As described above, a bias magnetic field is applied to first magnetization free layer 13A in second direction Y by first magnet layers 21A and 22A. For the above reasons, first magnetization free layer 13A is magnetized in second direction Y when no external magnetic field is applied (hereinafter, referred to as a zero magnetic field). Similarly, second magnetization free layer 13B is formed longer in first direction X than in second direction Y. Therefore, the magnetization direction of second magnetization free layer 13B is easily oriented to first direction X by the shape anisotropy effect. As described above, a bias magnetic field is applied to second magnetization free layer 13B in first direction X by second magnet layers 21B and 22B. For the above reasons, second magnetization free layer 13B is magnetized in first direction X in a zero magnetic field. However, the shapes of first magnetization free layer 13A and second magnetization free layer 13B are not limited to those described above. For example, first magnetization free layer 13A may be square when viewed from third direction Z, or may be formed so that first direction X is longer than second direction Y. The same applies to second magnetization free layer 13B.

First magnetization fixed layer 11A is magnetized in first direction X. When an external magnetic field is applied in first direction X, the magnetization direction of first magnetization free layer 13A in FIG. 2 rotates clockwise or counterclockwise depending on the strength of the external magnetic field. This rotation changes the relative angle between the magnetization direction of first magnetization fixed layer 11A and the magnetization direction of first magnetization free layer 13A and thus changes the electrical resistance of first magnetic field sensing element 2A to the sense current. Based on this change in electrical resistance, first magnetic field sensing element 2A detects the strength of the external magnetic field in the magnetic field sensing direction (first direction X). Second magnetic field sensing element 2B also detects the strength of the external magnetic field in the magnetic field sensing direction (second direction Y) by a similar principle.

Next, a method for manufacturing the above-described magnetic sensor 1 will be described. First, lower electrode layers 6, laminated bodies 7, and upper electrode layers 14 are formed on substrate 3 for each of first magnetic field sensing element 2A and second magnetic field sensing element 2B. First magnetization fixed layer 11A of first laminated body 7A and second magnetization fixed layer 11B of second laminated body 7B can be magnetized by, for example, a method that combines application of a magnetic field and local heating. Specifically, while applying an external magnetic field from first direction X, first magnetic field sensing element 2A (first magnetization fixed layer 11A) is irradiated with laser light to heat first magnetic field sensing element 2A (first magnetization fixed layer 11A). Next, while applying an external magnetic field from second direction Y, second magnetic field sensing element 2B (second magnetization fixed layer 11B) is irradiated with laser light to heat second magnetic field sensing element 2B (second magnetization fixed layer 11B). By this method, first magnetization fixed layer 11A and second magnetization fixed layer 11B that are supported by the same substrate 3 can be magnetized in different directions.

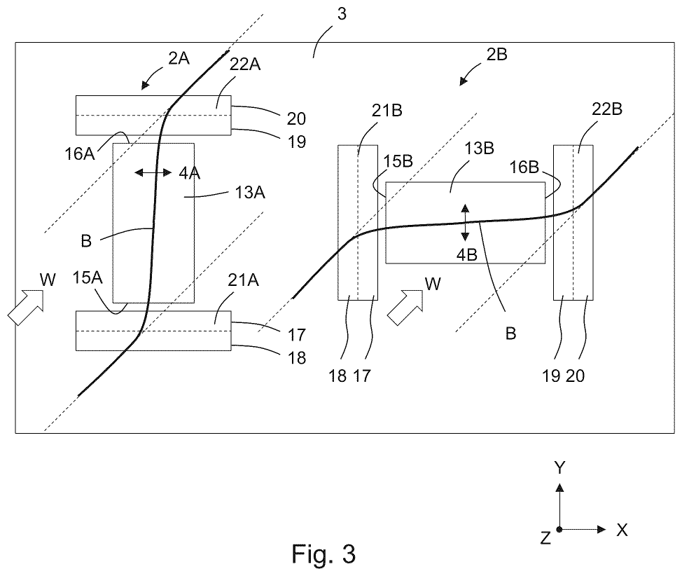

Next, first magnet layers 21A and 22A and the second magnet layers 21B and 22B are formed. Subsequently, first magnet layers 21A and 22A and second magnet layers 21B and 22B are magnetized. As shown in FIG. 3, an external magnetic field is applied from direction W that is at approximately the same angle to each of first direction X and second direction Y to magnetize first magnet layers 21A and 22A and second magnet layers 21B and 22B. This process is performed with first magnet layers 21A and 22A and second magnet layers 21B and 22B supported on substrate 3 such that first magnet layers 21A and 22A and second magnet layers 21B and 22B can be magnetized simultaneously. Thereafter, upper electrode layers 14 of first magnetic field sensing element 2A and second magnetic field sensing element 2B are formed. Direction W may be inclined at 45 degrees from each of first direction X and second direction Y, but direction W may vary within a slight range (for example, from about 43 to 47 degrees).

In FIG. 3, magnetic flux generated by a magnetic field application device (not shown) such as an electromagnet flows from the lower left to the upper right (in direction W). First magnet layer 21A on the lower side in the drawing is located on the upstream side in terms of the direction in which the external magnetic field is applied, and first magnet layer 22A on the upper side in the drawing is located on the downstream side in terms of the direction in which the external magnetic field is applied. Therefore, first magnet layer 21A on the lower side in the figure is referred to as first upstream magnet layer 21A, and first magnet layer 22A on the upper side in the figure is referred to as first downstream magnet layer 22A. Also, a part of magnetic flux B that enters lower first magnet layer 21A in the figure passes through first magnetization free layer 13A and upper first magnet layer 22A and exits from upper first magnet layer 22A. Therefore, the lower end of first magnetization free layer 13A is referred to as first upstream end 15A in the application direction of the external magnetic field, and the upper end is referred to as first downstream end 16A in the application direction of the external magnetic field. First upstream magnet layer 21A faces first upstream end 15A of first magnetization free layer 13A, and first downstream magnet layer 22A faces first downstream end 16A of first magnetization free layer 13A. The same applies to second magnet layers 21B and 22B. Second upstream magnet layer 21B faces second upstream end 15B of second magnetization free layer 13B, and second downstream magnet layer 22B faces second downstream end 16B of second magnetization free layer 13B.

As shown in FIG. 3, magnetic flux B that passes through first upstream magnet layer 21A, first magnetization free layer 13A, and first downstream magnet layer 22A bends inside first upstream magnet layer 21A and slants in second direction Y, proceeds in roughly second direction Y in first magnetization free layer 13A, and bends again in first downstream magnet layer 22A to be directed in the application direction W of the external magnetic field. In other words, since first magnetization free layer 13A has a magnetic flux collecting function or a function as a yoke, the path of magnetic flux B is bent to follow first magnetization free layer 13A.

By utilizing this phenomenon, first magnet layers 21A and 22A can be magnetized at an angle closer to second direction Y than to the application direction W of the external magnetic field. When first upstream magnet layer 21A is divided in second direction Y into half-portion 17 that is close to first magnetization free layer 13A and another half-portion 18 that is more distant from first magnetization free layer 13A, the average magnetization direction of half-portion 17 is inclined more toward second direction Y than the average magnetization direction of the other half-portion 18. The average magnetization direction means the average of the magnetization directions of the individual grains of first magnet layer 21A. Similarly, when first downstream magnet layer 22A is divided in second direction Y into half-portion 19 that is close to first magnetization free layer 13A and another half-portion 20 that is more distant from first magnetization free layer 13A, the average magnetization direction of half-portion 19 is inclined more toward second direction Y than the average magnetization direction of the other half-portion 20. As a result, the angle between the average magnetization direction of each of two first magnet layers 21A and 22A and second direction Y is between more than 0 degrees and less than 45 degrees. Regarding the direction of the bias magnetic field applied to first magnetization free layer 13A, the contribution of the magnetization direction of half-portion 17 of first upstream magnet layer 21A and half-portion 19 of first downstream magnet layer 22A is relatively large. Therefore, according to this embodiment, a bias magnetic field that is oriented in second direction Y can be applied to first magnetization free layer 13A. The same applies to second magnetization free layer 13B.

As shown in FIG. 2, centerline 24A of first magnetization free layer 13A that is parallel to second direction Y coincides with centerlines 25A and 26A of first magnet layers 21A and 22A that are parallel to second direction Y. This arrangement allows the bias magnetic field applied to first magnetization free layer 13A to be directed more along second direction Y. Dimension D1A in first direction X of first magnet layers 21A and 22A may be greater than dimension D2A in first direction X of first magnetization free layer 13A. This arrangement enables the application of a bias magnetic field oriented in second direction Y across the entire width in first direction X of first magnetization free layer 13A.

The same arrangement applies to second magnet layers 21B and 22B. In each of second magnet layers 21B and 22B, the magnetization directions of half-portions 17 and 19 that are close to second magnetization free layer 13B are inclined toward first direction X relative to the magnetization direction of other half-portions 18 and 20 that are more distant from second magnetization free layer 13B. The angle between the average magnetization direction of each of second magnet layers 21B and 22B and first direction X is between more than 0 degrees and less than 45 degrees. As shown in FIG. 2, centerline 24B of second magnetization free layer 13B that is parallel to first direction X coincides with centerlines 25B and 26B of second magnet layers 21B and 22B that are parallel to first direction X. Dimension D1B in second direction Y of second magnet layers 21B and 22B is greater that dimension D2B in second direction Y of second magnetization free layer 13B.

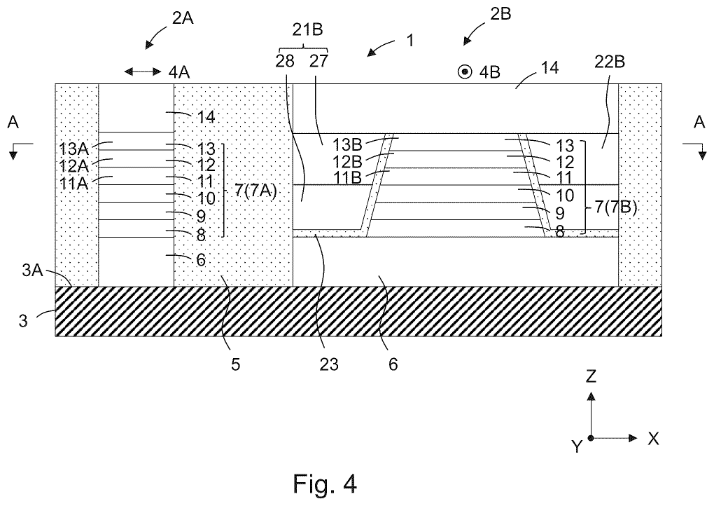

FIG. 4 is a cross-sectional view showing a schematic configuration of magnetic sensor 1 according to another modification of the first embodiment. Description of configurations and effects that are the same those of the first embodiment is here omitted. As shown in FIG. 4, two second magnet layers 21B and 22B each have ferromagnetic layer 27 and antiferromagnetic layer 28, and ferromagnetic layers 27 face second magnetization free layer 13B in first direction X. Although not shown, first magnet layers 21A and 22A also each have ferromagnetic layer 27 and antiferromagnetic layer 28, and ferromagnetic layers 27 face first magnetization free layer 13A in second direction Y. Ferromagnetic layer 27 is made of CoFe. Antiferromagnetic layer 28 is made of an alloy such as IrMn, Fe-Mn, Ni-Mn, Pt-Mn, or Pd-Pt-Mn, and is strongly exchange-coupled with adjacent ferromagnetic layer 27. Ferromagnetic layer 27 applies a bias magnetic field to magnetization free layer 13, as do first and second magnet layers 21A, 22A, 21B, and 22B in the first embodiment. The magnetization direction of ferromagnetic layer 27 is firmly fixed by antiferromagnetic layer 28 and thus reduces hysteresis in first and second magnet layers 21A, 22A, 21B, and 22B in a zero magnetic field. The exchange coupling between antiferromagnetic layer 28 and ferromagnetic layer 27 is achieved by locally heating ferromagnetic layer 27 and antiferromagnetic layer 28 in a state in which an external magnetic field is applied. In other words, each of ferromagnetic layers 27 is magnetized by locally heating each of two first magnet layers 21A and 22A and two second magnet layers 21B and 22B while the external magnetic field is applied.

### Second Embodiment

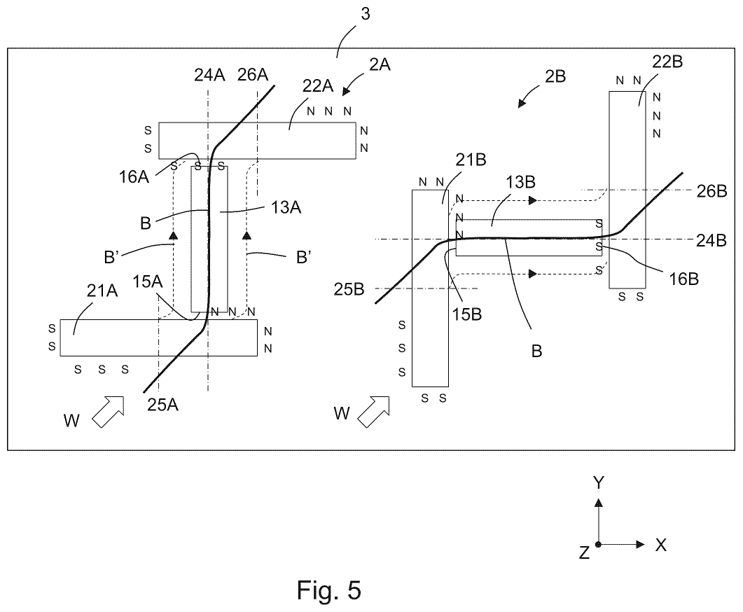

FIG. 5 is a view similar to FIG. 2 of magnetic sensor 1 according to the second embodiment and shows a plan view of the magnetization free layers and the magnet layers. Description of configurations and effects that are the same as those of the first embodiment is here omitted. In this embodiment, first magnetic field sensing element 2A and second magnetic field sensing element 2B have the same configuration, and first (or second) magnetic field sensing element 2A (2B) that is rotated 90 degrees on the XY plane corresponds to second (or first) magnetic field sensing element 2B (2A). Therefore, the following description will mainly focus on first magnetic field sensing element 2A.

In this embodiment, centerline 24A of first magnetization free layer 13A is parallel to second direction Y and centerlines 25A and 26A of first magnet layers 21A and 22A are parallel to second direction Y but are offset from each other in first direction X. Specifically, centerline 24A of first magnetization free layer 13A is located between centerline 25A of first upstream magnet layer 21A and centerline 26A of first downstream magnet layer 22A, and centerline 25A of first upstream magnet layer 21A is located to precede centerline 26A of first downstream magnet layer 22A in application direction W of the external magnetic field. Since magnetic flux B is applied from the lower left and toward the upper right in FIG. 5, first upstream magnet layer 21A and first downstream magnet layer 22A are magnetized with south pole at the lower left and north pole at the upper right, respectively. Therefore, the N-pole of first upstream magnet layer 21A and the S-pole of first downstream magnet layer 22A are roughly opposite each other in second direction Y, and magnetic field B′ that is directed in second direction Y is formed around first magnetization free layer 13A. As a result, first magnetization free layer 13A is magnetized in a direction closer to second direction Y. In addition, in first direction X, only one of centerlines 25A and 26A may deviate from centerline 24A.

Similarly, centerline 24B of second magnetization free layer 13B that is parallel to first direction X and centerlines 25B and 26B of second magnet layers 21B and 22B that are parallel to first direction X are offset from each other in second direction Y. Specifically, centerline 24B of second magnetization free layer 13B is located between centerline 25B of second upstream magnet layer 21B and centerline 26B of second downstream magnet layer 22B, and centerline 25B of second upstream magnet layer 21B is located to precede centerline 26B of second downstream magnet layer 22B in application direction W of the external magnetic field. In addition, only one of centerlines 25B and 26B may deviate in second direction Y from centerline 24B.

### Third Embodiment

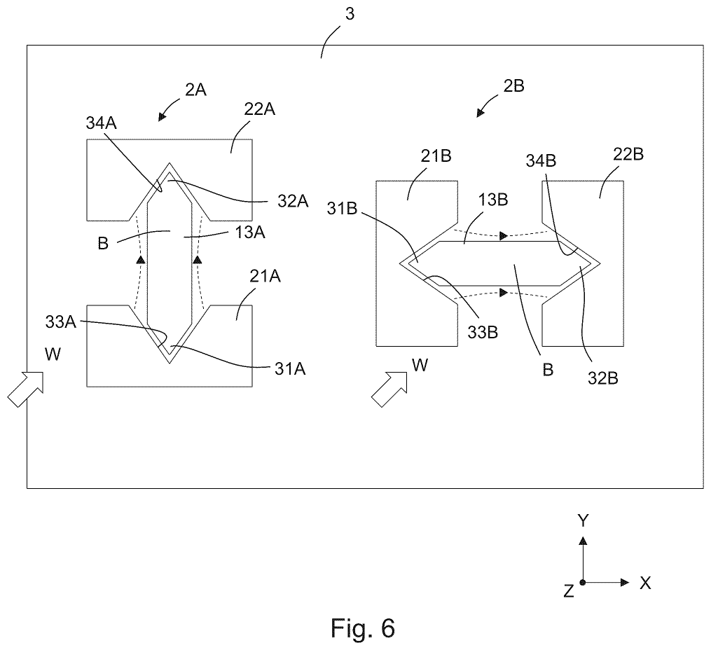

FIG. 6 is a view similar to FIG. 2 of magnetic sensor 1 according to the third embodiment and shows a plan view of the magnetization free layers and the magnet layers. Description of configurations and effects that are the same as those of the first embodiment is here omitted. In this embodiment, first magnetic field sensing element 2A and second magnetic field sensing element 2B have the same configuration, and first (or second) magnetic field sensing element 2A (2B) that is rotated 90 degrees on the XY plane corresponds to second (or first) magnetic field sensing element 2B (2A). Therefore, the following description will mainly focus on first magnetic field sensing element 2A.

First magnetization free layer 13A includes triangular first upstream end region 31A that faces first upstream magnet layer 21A and triangular first downstream end region 32A that faces first downstream magnet layer 22A. First upstream magnet layer 21A includes first upstream recess 33A that accommodates first upstream end region 31A, and first downstream magnet layer 22A includes first downstream recess 34A that accommodates first downstream end region 32A. Similarly, second magnetization free layer 13B includes triangular second upstream end region 31B that faces second upstream magnet layer 21B, and triangular second downstream end region 32B that faces second downstream magnet layer 22B. Second upstream magnet layer 21B includes second upstream recess 33B that accommodates second upstream end region 31B, and second downstream magnet layer 22B includes second downstream recess 34B that accommodates second downstream end region 32B.

When first magnetization free layer 13A has a rectangular shape when viewed from third direction Z, a demagnetizing field is generated at the end of first magnetization free layer 13A that face first magnet layers 21A and 22A. Because of the effect of the demagnetizing field, oblique magnetization may remain at the ends of first magnetization free layer 13A that face first magnet layers 21A and 22A even when the external magnetic field disappears, and this oblique magnetization causes hysteresis in the output of magnetic sensor 1. In this embodiment, in contrast, end regions 31A and 32A of first magnetization free layer 13A that face first magnet layers 21A and 22A are formed with a triangular shape that therefore reduces the effect of the demagnetizing field and thus reduces hysteresis. The same effect applies to second magnetic field sensing element 2B.

### Fourth Embodiment

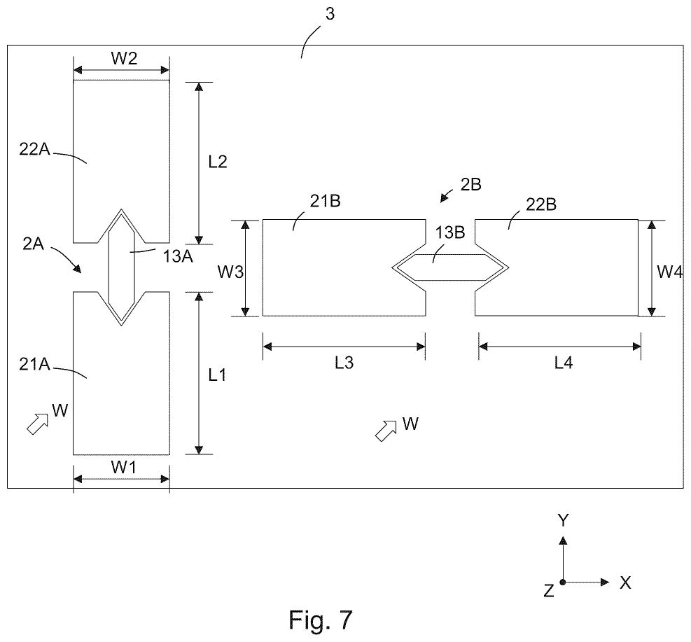

FIG. 7 is a view similar to FIG. 6 of magnetic sensor 1 according to the fourth embodiment and shows a plan view of the magnetization free layer and the magnet layers. Description of configurations and effects that are the same as those of the third embodiment is here omitted. The configurations and effects of which description has been omitted are the same as those of the third embodiment. In this embodiment, first magnetic field sensing element 2A and second magnetic field sensing element 2B have the same configuration, and first (or second) magnetic field sensing element 2A (2B) that is rotated 90 degrees on the XY plane corresponds to second (or first) magnetic field sensing element 2B (2A). In this embodiment, dimension L1 in second direction Y of first upstream magnet layer 21A of first magnetic field sensing element 2A is greater than dimension W1 in first direction X, and dimension L2 in second direction Y of first downstream magnet layer 22A is greater than dimension W2 in first direction X. This arrangement causes the effect of shape anisotropy of first upstream magnet layer 21A and first downstream magnet layer 22A to be exerted in a direction that aligns with second direction Y, and first magnetization free layer 13A is therefore magnetized in a direction closer to second direction Y. Similarly, dimension L3 in first direction X of first upstream magnet layer 21B of second magnetic field sensing element 2B is greater than dimension W3 in second direction Y, and dimension L4 in first direction X of second downstream magnet layer 22B is greater than dimension W4 in second direction Y. This arrangement causes the effect of shape anisotropy of second upstream magnet layer 21B and second downstream magnet layer 22B to be exerted in a direction that aligns with first direction X, and second magnetization free layer 13B is therefore magnetized in a direction closer to first direction X. Although not shown in the drawings, this embodiment can be combined with the first to third embodiments and the fifth and sixth embodiments.

### Fifth Embodiment

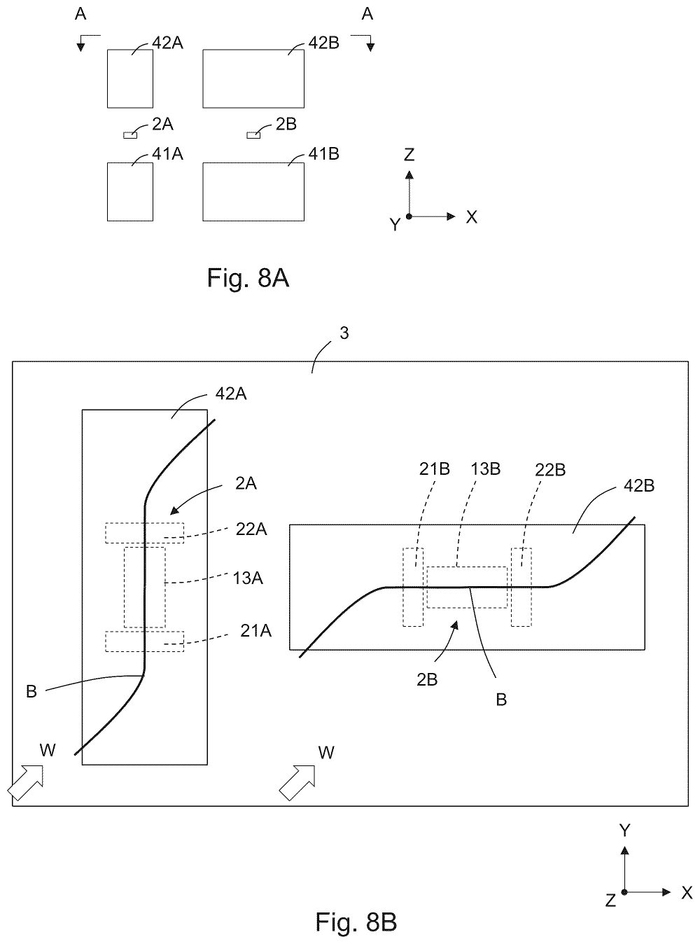

FIGS. 8A and 8B show the configuration of magnetic sensor 1 according to the fifth embodiment. Description of configurations and effects that are the same as those of the first embodiment is here omitted. FIG. 8A is a side view of magnetic sensor 1 as viewed from second direction Y. FIG. 8B is a diagram similar to FIG. 2 and shows a plan view of the magnetization free layer and the magnet layers taken along line AA in FIG. 8A. In this embodiment, first magnetic field sensing element 2A and second magnetic field sensing element 2B have the same configuration, and first (or second) magnetic field sensing element 2A (2B) that is rotated 90 degrees on the XY plane corresponds to second (or first) magnetic field sensing element 2B (2A). Therefore, the following description will mainly focus on first magnetic field sensing element 2A.

In this embodiment, at least one (two in this embodiment) first shield layer 41A and 42A is provided to shield first magnetic field sensing element 2A, and at least one (two in this embodiment) second shield layer 41B and 42B is provided to shield second magnetic field sensing element 2B. First shield layers 41A and 42A are elongated in second direction Y, and second shield layers 41B and 42B are elongated in first direction X. First shield layers 41A and 42A sandwich first magnetic field sensing element 2A in third direction Z, and second shield layers 41B and 42B sandwich second magnetic field sensing element 2B in third direction Z. First shield layers 41A and 42A and second shield layers 41B and 42B are made of a soft magnetic material such as NiFe.

In general, a soft magnetic material having an elongated shape has a property such that magnetization is easily saturated in the longitudinal direction but not easily saturated in the lateral direction. Therefore, first shield layers 41A and 42A shield against an external magnetic field in first direction X while magnetization in second direction Y is easily saturated, whereby first shield layers 41A and 42A no longer function as a shield. When the external magnetic field is too strong, the shielding effect in first direction X is also reduced. The external magnetic field may have strength at least in first direction X that does not cause magnetic saturation of first shield layers 41A and 42A. As a result, the component of the external magnetic field in second direction Y predominates around first shield layers 41A and 42A, and as shown in FIG. 8B, the external magnetic field applied to first magnetic field sensing element 2A tends to be oriented in second direction Y. The same effect applies to second magnetic field sensing element 2B. Although FIG. 8B shows first and second magnetic field sensing elements 2A and 2B of the first embodiment, this embodiment can also be combined with the second or third embodiment.

### Sixth Embodiment

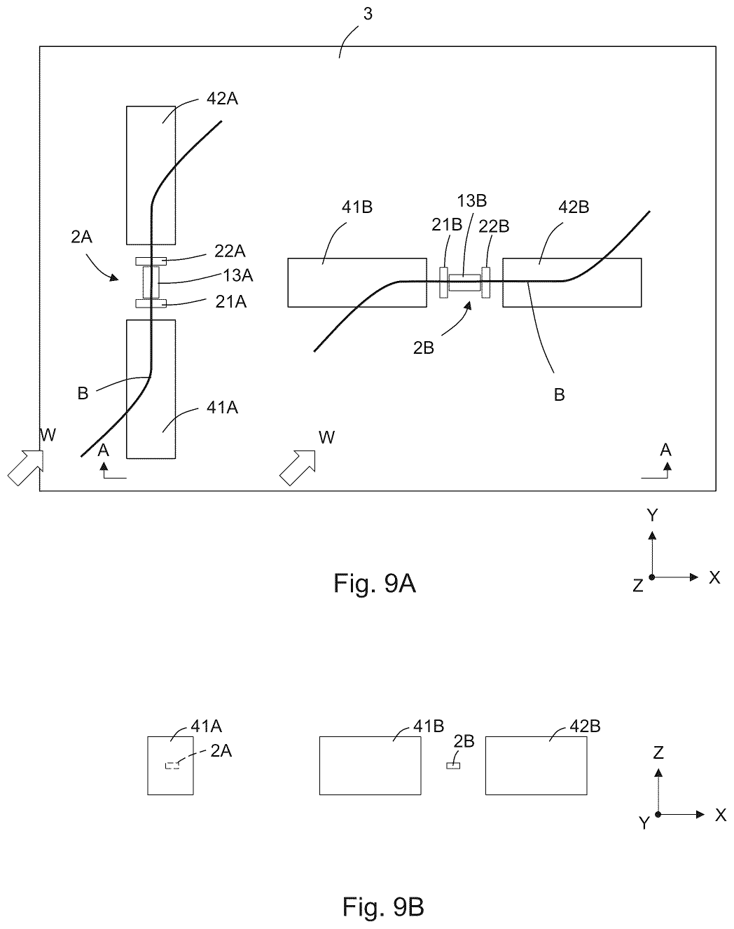

FIGS. 9A and 9B show the configuration of magnetic sensor 1 according to the sixth embodiment. Description of configurations and effects that are the same as those of the fifth embodiment is here omitted. FIG. 9A is similar to FIG. 2 and shows a plan view of magnetic sensor 1 as viewed from third direction Z. FIG. 9B shows a side view of the magnetization free layer and the magnet layers taken along line AA in FIG. 9A. In this embodiment, first magnetic field sensing element 2A and second magnetic field sensing element 2B have the same configuration, and first (or second) magnetic field sensing element 2A (2B) that is rotated 90 degrees on the XY plane corresponds to second (or first) magnetic field sensing element 2B (2A).

The configurations of first shield layers 41A and 42A and second shield layers 41B and 42B are the same as in the fifth embodiment, but two first shield layers 41A and 42A sandwich first magnetic field sensing element 2A in second direction Y, and two second shield layers 41B and 42B sandwich second magnetic field sensing element 2B in first direction X. In this configuration as well, the component of the external magnetic field in second direction Y predominates around first shield layers 41A and 42A, whereby the same effect can be obtained. In addition, in the fifth and sixth embodiments, one first shield layer 41A or 42A may be arranged near first magnetic field sensing element 2A, and one second shield layer 41B or 42B may be arranged near second magnetic field sensing element 2B. In other words, one of first shield layers 41A or 42A and one of second shield layers 41B or 42B in the fifth and sixth embodiments may be omitted.

According to the present disclosure, a manufacturing method can be provided for a magnetic sensor that allows a plurality of magnet layers to be magnetized to different magnetization states in a single process.

### LIST OF REFERENCE NUMERALS

1 magnetic sensor
2A first magnetic field sensing element
2B second magnetic field sensing element
3 substrate
11A first magnetization fixed layer
11B second magnetization fixed layer
12A first spacer layer
12B second spacer layer
13A first magnetization free layer (first soft magnetic layer)
13B second magnetization free layer (second soft magnetic layer)
15A first upstream end
15B second upstream end
16A first downstream end
16B second downstream end
21A first upstream magnet layer
21B second upstream magnet layer
22A first downstream magnet layer
22B second downstream magnet layer
24A centerline of the first magnetic free layer
24B centerline of the second magnetic free layer
25A centerline of the first upstream magnet layer
25B centerline of the second upstream magnet layer
26A centerline of the first downstream magnet layer
26B centerline of the second downstream magnet layer
27 ferromagnetic layer
28 antiferromagnetic layer
31A first upstream end region
31B second upstream end region
32A first downstream end region
32B second downstream end region
33A first upstream recess
33B second upstream recess
34A first downstream recess
34B second downstream recess
41A, 42A first shield layer
41B, 42B second shield layer
X first direction
Y second direction
Z third direction

1. A method for manufacturing a magnetic sensor comprising:
a first magnetic field sensing element that includes a magnetic field sensing axis approximately parallel to a first direction, two first magnet layers arranged in a second direction approximately perpendicular to the first direction, and a first soft magnetic layer that is sandwiched between the two first magnet layers in the second direction;
a second magnetic field sensing element that includes a magnetic field sensing axis approximately parallel to the second direction, two second magnet layers arranged in the first direction, and a second soft magnetic layer sandwiched between the two second magnet layers in the first direction; and
a substrate that supports the first magnetic field sensing element and the second magnetic field sensing element, the method comprising a step of:
applying an external magnetic field from a direction that is at approximately equal angles to each of the first direction and the second direction while the two first magnet layers, the two second magnet layers, the first soft magnetic layer, and the second soft magnetic layer are supported on the substrate, thereby magnetizing the two first magnet layers and the two second magnet layers.

2. The method for manufacturing a magnetic sensor according to claim 1, wherein:
the first magnetic field sensing element comprises a first magnetization free layer in which magnetization direction is caused to rotate by an external magnetic field, a first magnetization fixed layer in which magnetization direction is fixed in the first direction, and a nonmagnetic first spacer layer located between the first magnetization free layer and the first magnetization fixed layer;
the second magnetic field sensing element comprises a second magnetization free layer in which magnetization direction is caused to rotate by an external magnetic field, a second magnetization fixed layer in which magnetization direction is fixed in the second direction, and a nonmagnetic second spacer layer located between the second magnetization free layer and the second magnetization fixed layer; and
the first magnetization free layer is the first soft magnetic layer, and the second magnetization free layer is the second soft magnetic layer.

3. The method for manufacturing a magnetic sensor according to claim 2, wherein:
a centerline of the first magnetization free layer parallel to the second direction coincides with centerlines of the two first magnet layers parallel to the second direction; and
a centerline of the second magnetization free layer parallel to the first direction coincides with centerlines of the two second magnet layers parallel to the first direction.

4. The method for manufacturing a magnetic sensor according to claim 2, wherein:
the first magnetization free layer includes a first upstream end region and a first downstream end region in the application direction of the external magnetic field;
the two first magnet layers include a first upstream magnet layer that faces the first upstream end region, and a first downstream magnet layer that faces the first downstream end region;
a centerline of the first magnetization free layer parallel to the second direction is between centerlines of the two first magnet layers parallel to the second direction;
a centerline of the first upstream magnet layer parallel to the second direction is on the upstream side in the application direction of the external magnetic field with respect to a centerline of the first downstream magnet layer parallel to the second direction;
the second magnetization free layer includes a second upstream end region and a second downstream end region in the application direction of the external magnetic field;
the two second magnet layers include a second upstream magnet layer that faces the second upstream end region and a second downstream magnet layer that faces the second downstream end region;
a centerline of the second magnetization free layer parallel to the first direction is between centerlines of the two second magnet layers parallel to the first direction; and
a centerline of the second upstream magnet layer parallel to the first direction is the upstream of a centerline of the second downstream magnet layer parallel to the first direction in the application direction of the external magnetic field.

5. The method for manufacturing a magnetic sensor according to claim 2, wherein:
a dimension of the first magnet layer in the first direction is greater than a dimension of the first magnetization free layer in the first direction; and
a dimension of the second magnet layer in the second direction is greater than a dimension of the second magnetization free layer in the second direction.

6. The method for manufacturing a magnetic sensor according to claim 2, wherein:
the first magnetic free layer includes two triangular first end regions that each face a respective one of the two first magnet layers; and
the second magnetization free layer includes two triangular second end regions that each face a respective one of the two second magnet layers.

7. The method for manufacturing a magnetic sensor according to claim 6, wherein:
the two first magnet layers each include a first recess that accommodates a respective one of the first end regions; and
the two second magnet layers each include a second recess that accommodates a respective one of the second end regions.

8. The method for manufacturing a magnetic sensor according to claim 2, further comprising steps of:
after forming the first magnetization fixed layer, heating the first magnetization fixed layer while applying a magnetic field in the first direction to magnetize the first magnetization fixed layer; and
after forming the second magnetization fixed layer, heating the second magnetization fixed layer while applying a magnetic field in the second direction to magnetize the second magnetization fixed layer.

9. The method for manufacturing a magnetic sensor according to claim 1, wherein:
the dimensions of each of the two first magnet layers in the second direction are greater than the dimensions of each of the two first magnet layers in the first direction; and
the dimensions of each of the two second magnet layers in the first direction are greater than the dimensions of each of the two second magnet layers in the second direction.

10. The method for manufacturing a magnetic sensor according to claim 1, the magnetic sensor further comprising:
at least one first shield layer that is elongated in the second direction and that shields the first magnetic field sensing element; and
at least one second shield layer that is elongated in the first direction and that shields the second magnetic field sensing element.

11. The method for manufacturing a magnetic sensor according to claim 10, wherein:
the at least one first shield layer includes two first shield layers that sandwich the first magnetic field sensing element in a third direction perpendicular to the first direction and the second direction; and
the at least one second shield layer includes two second shield layers that sandwich the second magnetic field sensing element in the third direction.

12. The method for manufacturing a magnetic sensor according to claim 10, wherein:
the at least one first shield layer includes two first shield layers that sandwich the first magnetic field sensing element in the second direction; and
the at least one second shield layer includes two second shield layers that sandwich the second magnetic field sensing element in the first direction.

13. The method for manufacturing a magnetic sensor according to claim 1, wherein
each of the two first magnet layers and the two second magnet layers are made of a hard-magnetic material.

14. The method for manufacturing a magnetic sensor according to claim 1, wherein
each of the two first magnet layers and the two second magnet layers includes a ferromagnetic layer and an antiferromagnetic layer, and each of the ferromagnetic layers is magnetized by locally heating each of the two first magnet layers and the two second magnet layers while the external magnetic field is applied.

15. A magnetic sensor, comprising:
a first magnetic field sensing element that includes a magnetic field sensing axis parallel to a first direction;
a second magnetic field sensing element that includes a magnetic field sensing axis parallel to a second direction approximately perpendicular to the first direction; and
a substrate that supports the first magnetic field sensing element and the second magnetic field sensing element, wherein:
the first magnetic field sensing element includes a first magnetization free layer in which magnetization direction is caused to rotate by an external magnetic field, a first magnetization fixed layer in which magnetization direction is fixed in the first direction, a nonmagnetic first spacer layer located between the first magnetization free layer and the first magnetization fixed layer, and two first magnet layers that are arranged in the second direction and that sandwich the first magnetization free layer in the second direction; and
the second magnetic field sensing element includes a second magnetization free layer in which magnetization direction is caused to rotate by an external magnetic field, a second magnetization fixed layer in which magnetization direction is fixed in the second direction, a nonmagnetic second spacer layer located between the second magnetization free layer and the second magnetization fixed layer, and two second magnet layers that are arranged in the first direction and that sandwich the second magnetization free layer in the first direction.

16. The magnetic sensor according to claim 15, wherein:
in each of the two first magnet layers, a magnetization direction of a half-portion close to the first magnetization free layer is more inclined toward the second direction than a magnetization direction of a remaining half-portion that is more distant from the first magnetization free layer; and
in each of the two second magnet layers, the magnetization direction of a half-portion close to the second magnetization free layer is more inclined toward the first direction than the magnetization direction of a remaining half-portion that is more distant from the second magnetization free layer.

17. The magnetic sensor according to claim 15, wherein:
an angle between an average magnetization direction of the two first magnet layers and the second direction is between 0 degrees and less than 45 degrees; and
an angle between an average magnetization direction of the two second magnet layers and the first direction is between more than 0 degrees and less than 45 degrees.
